(19) United States
(12) Patent Application Publication
(10) Pub. No.: US 2019/0033341 A1
(43) Pub. Date: Jan. 31, 2019

(54) MEMS-BASED THREE-AXIS ACCELERATION SENSOR

(71) Applicant: SHIN SUNG C&T CO., LTD., Seoul (KR)

(72) Inventors: Ci Moo SONG, Yongin-si (KR); Keun Jung YOUN, Dong-gu (KR); Do Hyeon LEE, Seoul (KR); Yong Kook KIM, Seoul (KR)

(73) Assignee: SHIN SUNG C&T CO., LTD., Seoul (KR)

(21) Appl. No.: 16/139,991

(22) Filed: Sep. 24, 2018

Related U.S. Application Data
(63) Continuation of application No. PCT/KR2017/003335, filed on Mar. 28, 2017.

(30) Foreign Application Priority Data
Jun. 29, 2016 (KR) 10-2016-0081591

(51) Int. Cl. G01P 15/125; G01P 15/18; B81B 3/00; B81B 7/02

(52) U.S. Cl. CPC G01P 15/125; G01P 15/18; G01P 2015/0814; B81B 7/02; B81B 3/0051

(57) ABSTRACT

The present invention relates to a MEMS-based three-axis acceleration sensor and, more specifically, comprises: an x-axis sensor mass sensing an external acceleration inputted in the direction of a first axis parallel to a bottom wafer substrate; a y-axis sensor mass sensing an external acceleration inputted in the direction of a second axis parallel to the bottom wafer substrate and perpendicular to the first axis; and a z-axis sensor mass formed so as to encompass the x-axis sensor mass and the y-axis sensor mass and sensing an external acceleration inputted in the direction of a third axis perpendicular to the bottom wafer substrate, wherein space is saved and accelerations in the three axis directions are respectively measured by sensing the independent movement of each axis sensor mass.

### CROSS-REFERENCE TO RELATED APPLICATION

This application is a continuation of International Patent Application No. PCT/KR2017/003335, filed Mar. 28, 2017, now pending, which claims foreign priority from Korean Patent Application No. 10-2016-0081591, filed on Jun. 29, 2016 in the Korean Intellectual Property Office, the disclosure of each document is incorporated herein by reference in their entirety.

### TECHNICAL FIELD

The present invention relates to an acceleration sensor, and more particularly, a MEMS-based three-axis acceleration sensor capable of sensing acceleration in each axial direction using the movement of x-, y-, and z-axis sensor masses.

### BACKGROUND ART

MEMS (Micro Electro Mechanical Systems) is a technique for achieving mechanical and electrical components using a semiconductor process, and a MEMS gyroscope which measures angular velocity and a MEMS acceleration sensor which measures acceleration are representative examples of utilizing MEMS technique. Generally, the movement of an object in a space may be described as a three-degree-of-freedom rotational movement and a three-degree-of-freedom linear movement. The three-degree-of-freedom rotational movement may be detected by x-, y-, and z-axis gyroscopes, and the three-degree-of-freedom linear movement may be detected by x-, y-, and z-axis acceleration sensors.

The gyroscope measures an angular velocity by measuring a Coriolis force generated when a rotational angular velocity is applied to an object moving at a predetermined speed. At this time, the Coriolis force is proportional to the cross product of the moving speed and the rotational angular speed due to the external force.

Further, in order to detect the generated Coriolis force, the gyroscope is provided with a mass which vibrates inside. Normally, a direction in which the mass in the gyroscope is driven is referred to as an excitation direction, a direction in which the rotational angular velocity is input to the gyroscope is referred to as an input direction, and a direction of detecting the Coriolis force generated in the mass is referred to as a sensing direction. The excitation direction, the input direction, and the sensing direction are set as mutually orthogonal directions on the space. Normally, gyroscopes utilizing the MEMS technique are classified into an x-axis (or y-axis) gyroscope and a z-axis gyroscope when a bottom wafer substrate thereof is viewed from an x-y plane.

On the other hand, the acceleration sensor, unlike the gyroscope, does not require an artificial excitation. Since external acceleration acts directly on a mass, the acceleration sensor can measure acceleration by detecting the displacement of the mass. Accordingly, the acceleration sensor is relatively simpler than the gyroscope. A MEMS acceleration sensor is classified into an x- or y-axis acceleration sensor capable of detecting acceleration in two axial directions parallel to a plane formed by a bottom wafer substrate or a z-axis acceleration sensor capable of detecting acceleration in a direction perpendicular to the plane. The y-axis acceleration sensor may be defined as an acceleration sensor whose input direction is parallel to the plane, and the y-axis acceleration sensor may be defined as an acceleration sensor whose direction in a direction perpendicular to the x axis on a plane. However, since the y-axis acceleration sensor is substantially the same as the x-axis acceleration sensor in principle, except for its installation direction, the x- and y-axis acceleration sensors may be collectively referred to as an xy-axis acceleration sensor.

Since the xy-axis acceleration sensor only needs to sense the vibration of a sensor mass in a plane, the sensor mass can be disposed in parallel to the bottom wafer substrate, and the movement of the sensor mass can be detected by a sensing electrode formed in a direction parallel to the bottom wafer substrate. On the other hand, the z-axis acceleration sensor needs to sense the movement of a sensor mass in a direction perpendicular to the bottom wafer substrate, but due to the nature of a MEMS device fabricated by depositing a wafer, it is difficult to implement the z-axis acceleration sensor in such a manner that the sensor mass and the sensing electrode can be arranged vertically.

Accordingly, there is known a z-axis MEMS acceleration sensor that senses an acceleration in a z-axis direction perpendicular to the x-y plane by using the pivotal movement of the sensor mass with respect to one rotation support axis. The z-axis MEMS acceleration sensor is composed of a fixed anchor, a rotation support axis for providing torsional stiffness, and a sensor mass rotatable about the rotation support axis.

At this time, a MEMS acceleration sensor may be separately provided for each axis, but the measurement of acceleration for all three axes may be desired. For this case, a three-axis integrated acceleration sensor is known.

FIG. 1 is a plan view of a conventional three-axis integrated acceleration sensor. Referring to FIG. 1, the conventional three-axis integrated acceleration sensor may be configured such that acceleration sensors for the three axes are arranged in series, or may be implemented as a square-type three-axis integrated acceleration sensor in which a z-axis MEMS acceleration sensor is disposed on a side where x- and y-axis MEMS acceleration sensors are arranged in consideration that the z-axis MEMS acceleration sensor occupies a large space. In other words, there does not exist an acceleration sensor for measuring acceleration for two or more axes at once, but acceleration sensors for the three axes are disposed on a single substrate to measure acceleration for all the three axes.

This type of approach, however, has problems. Generally, each acceleration sensor is provided with a sensing electrode and measures an acceleration value by measuring an increase or decrease in the static capacitance of the sensing electrode resulting from the movement of a sensor mass. Thus, disturbances may be generated between the sensing electrodes for their respective axes and by the sensor masses from different axes from the sensing electrodes.

Also, the z-axis acceleration sensor has a configuration for observing changes in static capacitance measured by the electrode at the bottom thereof upon vertical displacement to obtain a z-axis direction acceleration value. For a more precise measurement, the vertical displacement of the z-axis sensor mass needs to be large. Thus, in a case where the z-axis acceleration sensor uses the rotation of the z-axis sensor mass about a rotation axis connected in one direction, the longitudinal length of the z-axis sensor mass orthogonal to the rotation axis needs to be increased so as to increase the vertical displacement of the z-axis sensor mass.

For this reason, the z-axis acceleration sensor is longer than the other-axis acceleration sensors, and the size of the entire acceleration sensor is determined by the size of the z-axis acceleration sensor.

Also, in a case where the z-axis acceleration sensor uses rotation, the z-axis acceleration sensor makes its sensor mass seesaw about the rotation support axis by using a torsion spring, which generally provides torsional stiffness. Since the location at which the torsion spring supports the sensor mass is like a point, the sensor mass cannot maintain a straight line shape, but may be bent with both ends sagged down with respect to the axis thereof. Due to the bending of the sensor mass, the sensor mass is detected from below its original position, which, however, interferes with an accurate acceleration measurement by the sensing electrode.

### DISCLOSURE

### Technical Problems

To address the aforementioned problems, exemplary embodiments of the present invention provide a three-axis integrated acceleration sensor in which x-, y-, and z-axis sensor masses move independently and the movement of the x-, y-, and z-axis sensor masses can be detected independently. Particularly, the three-axis integrated acceleration sensor can precisely measure angular acceleration because the movement of the z-axis sensor mass in an x- or y-axis direction does not take place.

Additional advantages, subjects, and features of the present invention will be set forth in part in the description which follows and in part will become apparent to those having ordinary skill in the art upon examination of the following or may be learned from practice of the present invention.

### Technical Solutions

According to an aspect of the present invention, a three-axis integrated acceleration sensor includes: an x-axis sensor mass for sensing external acceleration input in a direction of a first axis that is parallel to a bottom wafer substrate; a y-axis sensor mass for sensing external acceleration input in a direction of a second axis that is parallel to the bottom wafer substrate and is orthogonal to the first axis; and a z-axis sensor mass formed to surround the x-axis sensor mass and the y-axis sensor mass, wherein the z-axis sensor mass is for sensing external acceleration input in a direction of a third axis that is orthogonal to the bottom wafer substrate.

The three-axis integrated acceleration sensor may be configured such that when external acceleration is sensed using the x-axis sensor mass, the y-axis sensor mass, or the z-axis sensor mass, the x-axis sensor mass, the y-axis sensor mass, and the z-axis sensor mass do not affect one another.

The x-axis sensor mass, the y-axis sensor mass, and the z-axis sensor mass may be disposed in parallel to the bottom wafer substrate.

The x-axis sensor mass may vibrate along the first-axis direction when external acceleration is input in the first-axis direction, the y-axis sensor mass may vibrate along the second-axis direction when external acceleration is input in the second-axis direction, and the z-axis sensor mass may rotate about a rotation support axis, which is parallel to the second axis, when external acceleration is input in the third-axis direction.

The three-axis integrated acceleration sensor may further include: first springs supporting movement in a direction of the rotation of the z-axis sensor mass; second springs supporting movement in a direction of the vibration of the x-axis sensor mass; and third springs supporting movement in a direction of the vibration of the y-axis sensor mass.

The first springs may include at least two springs disposed on both ends of the rotation support axis to support the z-axis sensor mass, the second springs may include at least two springs disposed at the front and the rear of the direction of the vibration of the x-axis sensor mass to support the x-axis sensor mass, and the third springs include at least two springs disposed at the front and the rear of the direction of the vibration of the y-axis sensor mass to support the y-axis sensor mass.

The first springs may be connected to a dummy spring that is connected to the z-axis sensor mass, and the dummy spring may be formed to block movement of the z-axis sensor mass in the first-axis direction or in the second-axis direction.

The three-axis integrated acceleration sensor may further include: a first sensing electrode sensing displacement of the z-axis sensor mass; a second sensing electrode sensing displacement of the x-axis sensor mass; and a third sensing electrode sensing displacement of the y-axis sensor mass.

The second and third sensing electrodes may have a parallel plate beam structure or a comb structure.

The three-axis integrated acceleration sensor may further include: first shielding walls disposed with a gap from outer surfaces of the z-axis sensor mass; second shielding walls disposed with a gap from the x-axis sensor mass and the z-axis sensor mass; and third shielding walls disposed with a gap from the y-axis sensor mass and the z-axis sensor mass.

The first shielding walls, the second shielding walls, and the third shielding walls may be grounded.

The z-axis sensor mass may be heavier on one side than the other side thereof with respect to the rotation support axis.

The first springs, the second springs, and the third springs may be supported by anchors that have no movement.

The rotation support axis of the z-axis sensor mass may traverse between the x-axis sensor mass and the y-axis sensor mass.

### Advantageous Effects

According to exemplary embodiments of the present invention, at least the following advantages can be provided.

Sensor masses for their respective axes move independently and are electrically independent from one another due to shielding walls. Thus, no electrical disturbances may be caused between the sensor masses, and as a result, acceleration values can be measured with precision.

Since the movement of a z-axis sensor mass in an x- or y-axis direction does not occur, a z-axis acceleration value can be measured with precision.

Since the z-axis sensor mass surrounds the sensor masses of the other axes, space can be saved, and a sufficient length can be secured for a sensor mass that is elongated in a longitudinal direction. Therefore, a z-axis acceleration value can be measured with heightened sensitivity.

It will be appreciated by those skilled in the art that the effects that can be achieved with the present invention are not limited to what has been described above and other advantages of the present invention will be clearly understood from the following detailed description taken in conjunction with the accompanying drawings.

### BRIEF DESCRIPTION OF DRAWINGS

FIG. 1 is a plan view illustrating the structure of a conventional three-axis integrated acceleration sensor.

FIG. 2 is a perspective view of a three-axis integrated acceleration sensor according to an exemplary embodiment of the present invention.

FIG. 3 is a schematic view illustrating the operating principle of the three-axis integrated acceleration sensor according to an exemplary embodiment of the present invention.

FIG. 4 is a plan view of the three-axis integrated acceleration sensor according to an exemplary embodiment of the present invention.

FIG. 5 is a cross-sectional view, taken along line A-A′, of the three-axis integrated acceleration sensor of FIG. 3.

FIG. 6 is a perspective view illustrating a case where an x-axis sensor mass of the three-axis integrated acceleration sensor according to an exemplary embodiment of the present invention vibrates.

FIG. 7 is a free-body diagram of the x-axis sensor mass of the three-axis integrated acceleration sensor according to an exemplary embodiment of the present invention.

FIG. 8 is a perspective view illustrating a case where a z-axis sensor mass of the three-axis integrated acceleration sensor according to an exemplary embodiment of the present invention vibrates.

FIG. 9 is a free-body diagram of the z-axis sensor mass of the three-axis integrated acceleration sensor according to an exemplary embodiment of the present invention.

### BEST MODES FOR CARRYING OUT THE INVENTION

Advantages and/or characteristics of the present invention and a method of attaining them will become more readily apparent from the detailed description given hereinafter together with the attached drawings. However, it should be understood that the detailed description and specific examples while indicating preferred embodiments of the present invention are given by way of illustration only since various changes and modifications within the spirit and scope of the present invention will become apparent to those skilled in the art from this detailed description. Like reference numerals designate like elements throughout the specification.

Unless otherwise defined, all terms (including technical and scientific terms) used in this specification may be used as the same meaning which may be commonly understood by the person with ordinary skill in the art, to which the present invention belongs. It will be further understood that terms defined in commonly used dictionaries should not be interpreted in an idealized or excessive sense unless expressly and specifically defined.

The terminology used herein is for the purpose of describing particular exemplary embodiments only and is not intended to be limiting of the present invention. As used herein, the singular forms are intended to include the plural forms as well, unless the context clearly indicates otherwise. It will be further understood that the terms “comprises” and/or “comprising,” when used in this specification, specify the presence of stated elements, steps, operations, and/or components, but do not preclude the presence or addition of one or more other elements, steps, operations, and/or components.

The present invention will be described with reference to cross-sectional views and/or schematic views, in which exemplary embodiments of the present invention are shown. Thus, the profile of an exemplary view may be modified according to manufacturing techniques and/or allowances. That is, the exemplary embodiments of the present invention are not intended to limit the scope of the present invention but cover all changes and modifications that can be caused due to a change in the manufacturing processes. For the convenience of description, constituent elements in the drawings of the present invention can be slightly enlarged or reduced. Additionally, the term “and/or” includes any and all combinations of one or more of the associated listed items. Furthermore, like numbers refer to like elements throughout.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

Exemplary embodiments of the present invention will now be described more fully hereinafter with reference to the accompanying drawings.

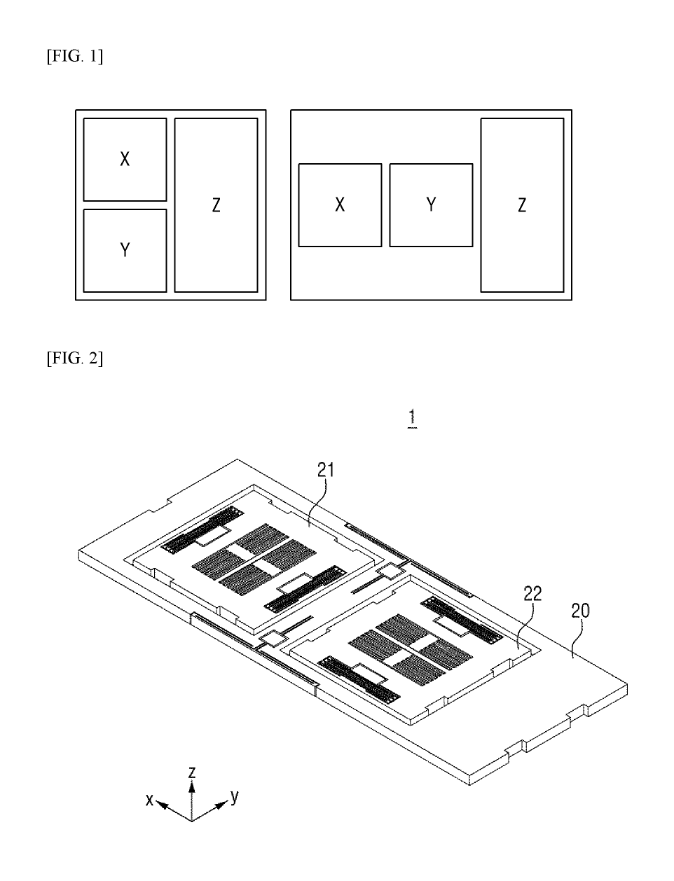

FIG. 2 is a perspective view of a three-axis integrated acceleration sensor 1 according to an exemplary embodiment of the present invention.

Referring to FIG. 2, the three-axis integrated acceleration sensor according to an exemplary embodiment of the present invention is largely composed of a z-axis sensor mass 20, an x-axis sensor mass 21, and a y-axis sensor mass 22. The sensor masses exist independently for their respective axes and vibrate or rotate to measure an acceleration for their respective axes.

As is apparent from FIG. 2, the z-axis sensor mass 20 may have a shape that includes the x-axis sensor mass 21 and the y-axis sensor mass 22. Thus, the z-axis sensor mass 20 is formed to be elongated in the direction in which the two sensor masses are arranged.

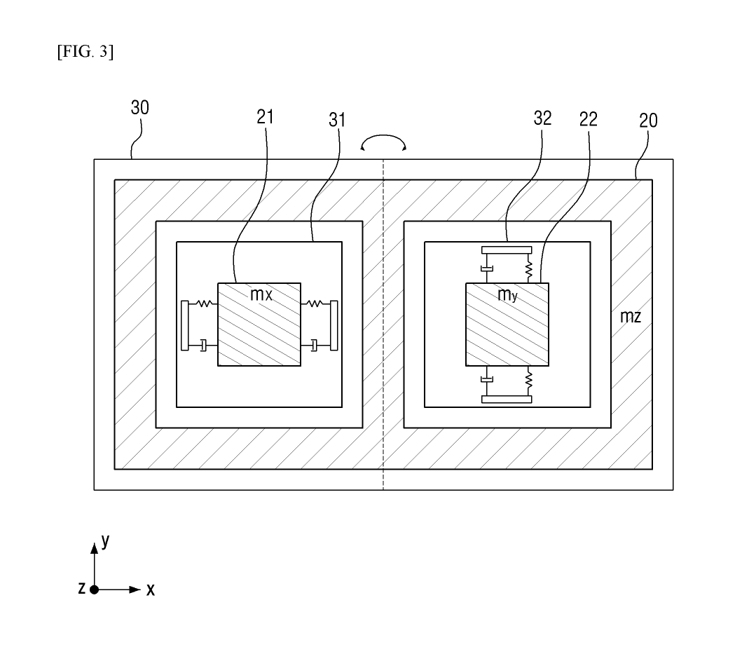

FIG. 3 is a schematic view illustrating the operating principle of the three-axis integrated acceleration sensor according to an exemplary embodiment of the present invention.

As described above with reference to FIG. 2, the three-axis integrated acceleration sensor includes sensor masses for their respective axes and is formed to have a structure in which the z-axis sensor mass 20 surrounds the x-axis sensor mass 21 and the y-axis sensor mass 22. Each sensor mass is physically/electrically separated by shielding walls (30, 31, and 32) so that the movement of one sensor mass cannot physically/electrically affect other sensor masses. The shielding walls (30, 31, and 32) may be grounded so that the influence on the sensing electrode of each sensor can be minimized.

The x-axis sensor mass 21 and the y-axis sensor mass 22 have their spring(s) and attenuator(s) connected in their axial direction and thus vibrate in their axial direction upon the application of acceleration from the outside in their respective axial directions. Each axial sensor calculates an acceleration value in their axial direction by measuring the displacement of such variation.

The z-axis sensor mass 20 rotates about a rotation support axis when a z-axis direction acceleration is applied from the outside. In this case, a z-axis acceleration sensor calculates the z-axis acceleration value by measuring the displacement of both ends of the z-axis sensor mass 20 in the z-axis direction. Here, the rotation support axis may be formed to traverse between the x-axis sensor mass 21 and the y-axis sensor mass 22.

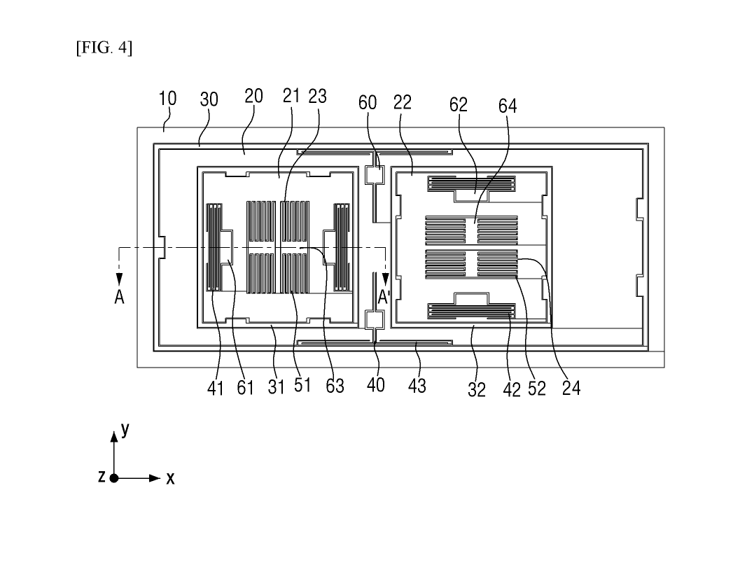

FIG. 4 is a plan view of the three-axis integrated acceleration sensor according to an exemplary embodiment of the present invention.

Referring to FIG. 4, the three-axis integrated acceleration sensor according to an exemplary embodiment of the present invention is provided with sealing walls 10 at an outermost periphery thereof so that all the elements thereof can be surrounded. The sealing walls 10 are for protecting the inner elements of the three-axis integrated acceleration sensor according to an exemplary embodiment of the present invention against the infiltration of external materials or impact and may be formed of a silicon wafer, plastic, or the like.

First shielding walls 30, which surround the other elements of the three-axis integrated acceleration sensor according to an exemplary embodiment of the present invention, are provided on the inside of the sealing walls 10. The shielding walls are for blocking the inside thereof from an external electromagnetic field and are formed of a silicon wafer or a metal. The first shielding walls 30 surround the z-axis sensor mass 20 to block the z-axis sensor mass 20 from an external electromagnetic field.

The z-axis acceleration sensor calculates the z-axis acceleration value by measuring the displacement of both ends of the z-axis sensor mass 20 upon the rotation of the z-axis sensor mass 20 when a z-axis direction acceleration is applied from the outside.

The z-axis sensor mass 20 has a rotation support axis in a latitudinal direction, and the rotation support axis is first springs 40. The first springs 40 are torsion springs and have torsional stiffness. Thus, the first springs 40 provide an elastic force to the rotation of the z-axis sensor mass 20 and thus allow the z-axis sensor mass 20 to seesaw.

The first springs 40 are again connected to a first anchor 60. In one exemplary embodiment of the present invention, the z-axis sensor mass 20 is allowed to seesaw about the rotation support axis by the first springs 40, which are connected to the first anchor 60 that has no movement. The first springs 40 cause a restoring torque so that the z-axis sensor mass 20 is restored to its normal position after a torsional deformation.

The first springs 40 are again connected to one end of a dummy spring 43. The dummy spring 43 is configured to extend in a longitudinal direction to be parallel to the z-axis sensor mass 20, and the other end of the dummy spring 43 is connected to the z-axis sensor mass 20. Accordingly, the z-axis sensor mass 20 is held so as to prevent the movement of the z-axis sensor mass 20 in the x-axis direction or the y-axis direction.

The z-axis sensor mass 20 may be configured to have a line symmetry about the rotation support axis, but in one exemplary embodiment, the z-axis sensor mass 20 may be configured to have one side longer than the other side. In this case, one side of the z-axis sensor mass 20 is heavier than the other side of the z-axis sensor mass 20 so that the weight is unbalanced, and the center of gravity of the z-axis sensor mass 20 on the x-z plane does not coincide with the rotation support axis. Thus, when a z-axis direction acceleration is applied, the z-axis sensor mass 20 rotates and seesaws.

The structure of an x-axis acceleration sensor will hereinafter be described with reference to FIG. 4.

The x-axis acceleration sensor calculates an x-axis direction acceleration value by measuring the displacement of the x-axis sensor mass 21, caused by the vibration of the x-axis sensor mass 21 upon the application of an x-axis direction acceleration from the outside. Thus, the x-axis acceleration sensor includes the x-axis sensor mass 21 and may be configured such that the elements thereof can be in line symmetry with respect to the x axis in order to prevent unnecessary movement in other directions.

The x-axis sensor mass 21, which is a sensor mass that vibrates along the x axis, i.e., the longitudinal direction of the three-axis integrated acceleration sensor, is disposed to be parallel to a bottom wafer substrate 11.

In order for the x-axis sensor mass 21 to vibrate along the x axis in response to the x-axis direction acceleration, the x-axis sensor mass 21 may be connected to second springs 41, which are arranged in the x-axis direction to be compressible and stretchable in the x-axis direction. A total of two second spring 41 may be connected to both ends of the x-axis sensor mass 21 in the x-axis direction to support x-axis direction movement and to provide an elastic force, but the present invention is not limited thereto. Any configuration that can provide an elastic force to the x-axis sensor mass 21 in the x-axis direction is possible such as a configuration in which the second springs 41 are disposed on a further inner side of the x-axis sensor mass 21.

In order to stably oscillate the x-axis sensor mass 21, the second springs 41 are connected to second anchors 61 that have no movement. The second anchors 61 are connected to the bottom wafer substrate 11 and are fixed regardless of the movement of the x-axis sensor mass 21 and other sensor masses. Accordingly, in the exemplary embodiment of the present invention where two springs at both ends in the x-axis direction are used to form the second springs 41, two second anchors 61 are needed to fix the two independent springs.

The second anchors 61 may be disposed on a further inner side of the x-axis sensor mass 21 than the second springs 41 so that second shielding walls 31 can become a physical limit for the vibration of the x-axis sensor mass 21, but various other configurations are also possible such as a configuration in which the second anchors 61 are disposed on a further outer side of the x-axis sensor mass 21 than the second springs 41 so that the second anchors 61 can become the physical limit for the vibration of the x-axis sensor mass 21.

To sense the displacement of the x-axis sensor mass 21, a sensing electrode is disposed. The sensing electrode of the x-axis acceleration sensor is for sensing the displacement of the x-axis sensor mass 21 in the x-axis direction and is preferably disposed to be parallel to a plane orthogonal to the x axis.

In one exemplary embodiment of the present invention, a second sensing electrode 51 is disposed at the center of the x-axis sensor mass 21 as a parallel plate electrode, but the location and the type of the second sensing electrode 51 are not particularly limited. That is, the second sensing electrode 51 may be disposed at either end of the x-axis sensor mass 21, or a comb electrode, instead of a parallel plate electrode, may be provided as the second sensing electrode 51.

Since a parallel plate electrode is used to improve the precision of acceleration measurement, an x-axis parallel plate beam structure 23 corresponding to the structure of the parallel plate electrode needs to be provided in the x-axis sensor mass 21. The x-axis parallel plate beam structure 23 is configured in such a manner that a sensor mass corresponding to the shape of the second sensing electrode 51 can extend between parallel plate beams of the second sensing electrode 51, which is a parallel plate electrode.

The second sensing electrode 51 is for measuring acceleration in the x-axis direction by sensing a variation in static capacitance, caused by the vibration of the x-axis sensor mass 21, and thus should not vibrate along with the x-axis sensor mass 21. Therefore, the second sensing electrode 51 is connected to a second sensing electrode anchor 63 not to move. The second sensing electrode anchor 63 is connected to the bottom wafer substrate 11, and the second sensing electrode 51 extends from the second sensing electrode 63 in two opposite directions along the y-axis direction, but the present invention is not limited thereto. That is, the second sensing electrode 51 may be configured to extend only in one direction. Thus, since the second sensing electrode 51 has no movement when the x-axis sensor mass 21 vibrates in the x-axis direction, displacement from the initial position between the x-axis parallel plate beam structure 23 and the second sensing electrode 51 is generated. As a result, a variation in the static capacitance of the second sensing electrode 51 is generated, and by measuring the variation in the static capacitance of the second sensing electrode 51, the x-axis acceleration value can be measured.

As already mentioned above, the z-axis sensor mass 20 is configured to surround the x-axis sensor mass 21. Since the x-axis sensor mass 21 and the z-axis sensor mass 20 need to be shielded from each other, the second shielding walls 31 may also exist between the x-axis sensor mass 21 and the z-axis sensor mass 20. The second shielding walls 31 are formed to surround the x-axis sensor mass 21 and are a predetermined gap apart from the z-axis sensor mass 20 and the x-axis sensor mass 21 so as not to be in direct contact with the z-axis sensor mass 20 and the x-axis sensor mass 21 because shielding walls must provide an electrical shielding, but must not interfere with the movement of a sensor mass.

The second shielding walls 31 may become a limit point for the vibration of the x-axis sensor mass 21. An acceleration sensor can measure only a certain range of acceleration values because of the physical limits thereof. The range of vibration of the x-axis sensor mass 21 can naturally become the range of acceleration values that can be measured by the x-axis acceleration sensor, and the boundaries of the range of acceleration values that can be measured by the x-axis acceleration sensor are determined by the second shielding walls 31 at both ends in the x-axis direction.

The second shielding walls 31, like the first shielding walls 30, are formed of a silicon wafer or a metallic material and block the x-axis sensor mass 21 from an external electromagnetic field.

The structure of a y-axis acceleration sensor will hereinafter be described with reference to FIG. 4.

The y-axis acceleration sensor calculates a y-axis direction acceleration value by measuring the displacement of the y-axis sensor mass 22, caused by the vibration of the y-axis sensor mass 22 upon the application of a y-axis direction acceleration from the outside. Thus, the y-axis acceleration sensor includes the y-axis sensor mass 22 and may be configured such that the elements thereof can be in line symmetry with respect to the y axis in order to prevent unnecessary movement in other directions.

The y-axis sensor mass 22, which is a sensor mass that vibrates along the y axis, i.e., the latitudinal direction of the three-axis integrated acceleration sensor, is disposed to be parallel to a bottom wafer substrate 11.

In order for the y-axis sensor mass 22 to vibrate along the y axis in response to the y-axis direction acceleration, the y-axis sensor mass 22 may be connected to third springs 42, which are arranged in the y-axis direction to be compressible and stretchable in the y-axis direction. A total of two third spring 42 may be connected to both ends of the y-axis sensor mass 22 in the y-axis direction to support y-axis direction movement and to provide an elastic force, but the present invention is not limited thereto. Any configuration that can provide an elastic force to the y-axis sensor mass 22 in the y-axis direction is possible such as a configuration in which the third springs 42 are disposed on a further inner side of the y-axis sensor mass 22.

In order to stably oscillate the y-axis sensor mass 22, the third springs 42 are connected to third anchors 62 that have no movement. The third anchors 62 are connected to the bottom wafer substrate 11 and are fixed regardless of the movement of the y-axis sensor mass 22 and other sensor masses. Accordingly, in the exemplary embodiment of the present invention where two springs at both ends in the y-axis direction are used to form the third springs 42, two third anchors 62 are needed to fix the two independent springs.

The third anchors 62 may be disposed on a further inner side of the y-axis sensor mass 22 than the third springs 42 so that third shielding walls 32 can become a physical limit for the vibration of the y-axis sensor mass 22, but various other configurations are also possible such as a configuration in which the third anchors 62 are disposed on a further outer side of the y-axis sensor mass 22 than the third springs 42 so that the third anchors 62 can become the physical limit for the vibration of the y-axis sensor mass 22.

To sense the displacement of the y-axis sensor mass 22, a sensing electrode is disposed. The sensing electrode of the y-axis acceleration sensor is for sensing the displacement of the y-axis sensor mass 22 in the y-axis direction and is preferably disposed to be parallel to a plane orthogonal to the y axis.

In one exemplary embodiment of the present invention, a third sensing electrode 52 is disposed at the center of the y-axis sensor mass 22 as a parallel plate electrode, but the location and the type of the third sensing electrode 52 are not particularly limited. That is, the third sensing electrode 52 may be disposed at either end of the y-axis sensor mass 22, or a comb electrode, instead of a parallel plate electrode, may be provided as the third sensing electrode 52.

Since a parallel plate electrode is used to improve the precision of acceleration measurement, a y-axis parallel plate beam structure 24 corresponding to the structure of the parallel plate electrode needs to be provided in the y-axis sensor mass 22. The y-axis parallel plate beam structure 24 is configured in such a manner that a sensor mass corresponding to the shape of the third sensing electrode 52 can extend between parallel plate beams of the third sensing electrode 52, which is a parallel plate electrode.

The third sensing electrode 52 is for measuring acceleration in the y-axis direction by sensing a variation in static capacitance, caused by the vibration of the y-axis sensor mass 22, and thus should not vibrate along with the y-axis sensor mass 22. Therefore, the third sensing electrode 52 is connected to a third sensing electrode anchor 64 not to move. The third sensing electrode anchor 64 is connected to the bottom wafer substrate 11, and the third sensing electrode 52 extends from the third sensing electrode 64 in two opposite directions along the x-axis direction, but the present invention is not limited thereto. That is, the third sensing electrode 52 may be configured to extend only in one direction. Thus, since the third sensing electrode 52 has no movement when the y-axis sensor mass 22 vibrates in the y-axis direction, displacement from an initial position is generated between the y-axis parallel plate beam structure 24 and the third sensing electrode 52. As a result, a variation in the static capacitance of the third sensing electrode 52 is generated, and by measuring the variation in the static capacitance of the third sensing electrode 52, the y-axis acceleration value can be measured.

As already mentioned above, the z-axis sensor mass 20 is configured to surround the y-axis sensor mass 22. Since the y-axis sensor mass 22 and the z-axis sensor mass 20 need to be shielded from each other, the third shielding walls 32 may also exist between the y-axis sensor mass 22 and the z-axis sensor mass 20. The second shielding walls 31 are formed to surround the x-axis sensor mass 21 and are a predetermined gap apart from the z-axis sensor mass 20 and the y-axis sensor mass 22 so as not to be in direct contact with the z-axis sensor mass 20 and the y-axis sensor mass 22 because shielding walls must provide an electrical shielding, but must not obstruct the movement of a sensor mass.

The third shielding walls 32 may become a limit point for the vibration of the y-axis sensor mass 22. An acceleration sensor can measure only a certain range of acceleration values because of the physical limits thereof. The range of vibration of the y-axis sensor mass 22 can naturally become the range of acceleration values that can be measured by the y-axis acceleration sensor, and the boundaries of the range of acceleration values that can be measured by the y-axis acceleration sensor are determined by the third shielding walls 32 at both ends in the y-axis direction.

The third shielding walls 32, like the first shielding walls and the second shielding walls 31, are formed of a silicon wafer or a metallic material and block the y-axis sensor mass 22 from an external electromagnetic field.

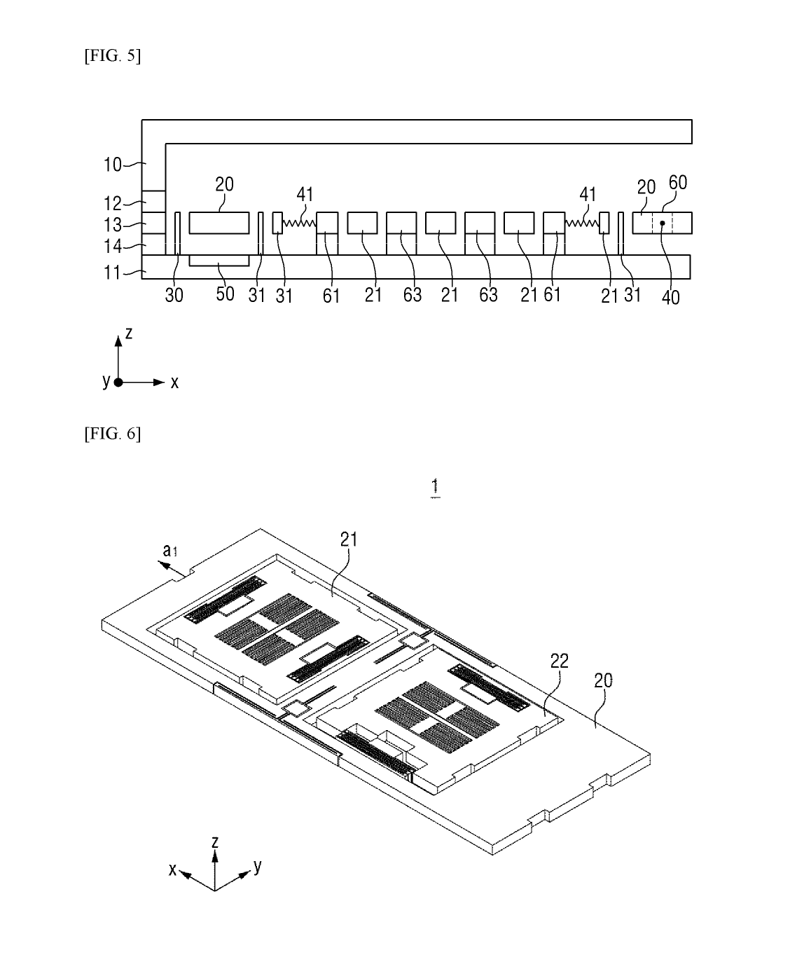

FIG. 5 is a cross-sectional view, taken along line A-A′, of the three-axis integrated acceleration sensor of FIG. 3.

Referring to FIG. 5, the three-axis integrated acceleration sensor according to an exemplary embodiment of the present invention has a structure in which the inner elements thereof are surrounded by the sealing walls (10, 12, 13, and 14) and the bottom wafer substrate 11.

The first sensing electrode 50, which senses the displacement of the z-axis sensor mass 20 based on a variation in static capacitance, cannot be seen in FIG. 4, which is a plan view, but can be seen in FIG. 5, which is a cross-sectional view, as being disposed at the location of the bottom wafer substrate 11 below the z-axis sensor mass 20.

As illustrated in FIG. 5, the sealing walls (30, 31, and 32) are not in direct contact with the sensor masses 20, 21, and 22, and the sensor masses 20, 21, and 22 are also not in contact with one another. The anchors 60, 61, 62, and 63 are fixed to the bottom wafer substrate 11 not to move. Accordingly, the sensor masses 20, 21, and 22 can move independently and do not affect one another when sensing acceleration.

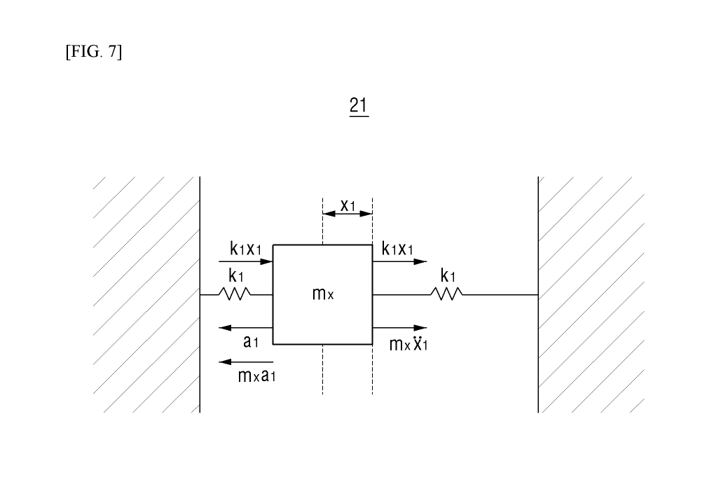

The operation and sensing principle of the three-axis integrated acceleration sensor according to an exemplary embodiment of the present invention upon the application of an x- or y-axis direction acceleration from the outside will hereinafter be described with reference to FIGS. 6 and 7.

FIG. 6 is a perspective view illustrating a case where the x-axis sensor mass 21 of the three-axis integrated acceleration sensor according to an exemplary embodiment of the present invention vibrates. The operating principle of the three-axis integrated acceleration sensor according to an exemplary embodiment of the present invention when the y-axis sensor mass 22 vibrates is the same as the operating principle of the three-axis integrated acceleration sensor according to an exemplary embodiment of the present invention when the x-axis sensor mass 21 vibrates, except for the direction of vibration and the elements acting, and thus, a description of the operating principle of the three-axis integrated acceleration sensor according to an exemplary embodiment of the present invention when the x-axis sensor mass 21 vibrates may be directly applicable thereto.

Referring to FIG. 6, in response to acceleration being applied to the three-axis integrated acceleration sensor according to an exemplary embodiment of the present invention from the outside in the x-axis direction, the x-axis sensor mass 21 moves in the x-axis direction. In this case, one of the second springs 41 disposed in the moving direction of the x-axis sensor mass 21 is compressed, and the other second spring 41 is stretched, thereby providing an elastic force to the x-axis sensor mass 21. The x-axis parallel plate beam structure 23 moves further from its original location in the moving direction with respect to the second sensing electrode 51. Thus, a variation in static capacitance is generated with respect to the second sensing electrode 51. The second sensing electrode 51 measures the static capacitance variation and converts it into an x-axis acceleration value.

FIG. 7 is a free-body diagram of the x-axis sensor mass 21 of the three-axis integrated acceleration sensor according to an exemplary embodiment of the present invention.

Referring to FIG. 7, assuming that the x axis lies horizontally, and that the x-axis sensor mass 21 moves by x₁ upon the application of acceleration from the outside in a leftward direction, the equation of motion for the x-axis acceleration sensor is as indicated by Equation 1.

mₓa₁=2k₁x₁+mₓ\ddot{x}₁

Here, mₓ denotes the mass of the x-axis sensor mass 21, k₁ denotes the rigidity of the third springs 42, and a₁ denotes acceleration exerted externally on the three-axis integrated acceleration sensor according to an exemplary embodiment of the present invention in the x-axis direction.

Referring to Equation 1, all the values except for a₁ and x₁ can be known in the process of designing, x₁ can be measured from a variation in the static capacitance of the second sensing electrode 51, and thus, only a₁ is left unknown. Accordingly, the acceleration applied externally in the x-axis direction can be calculated.

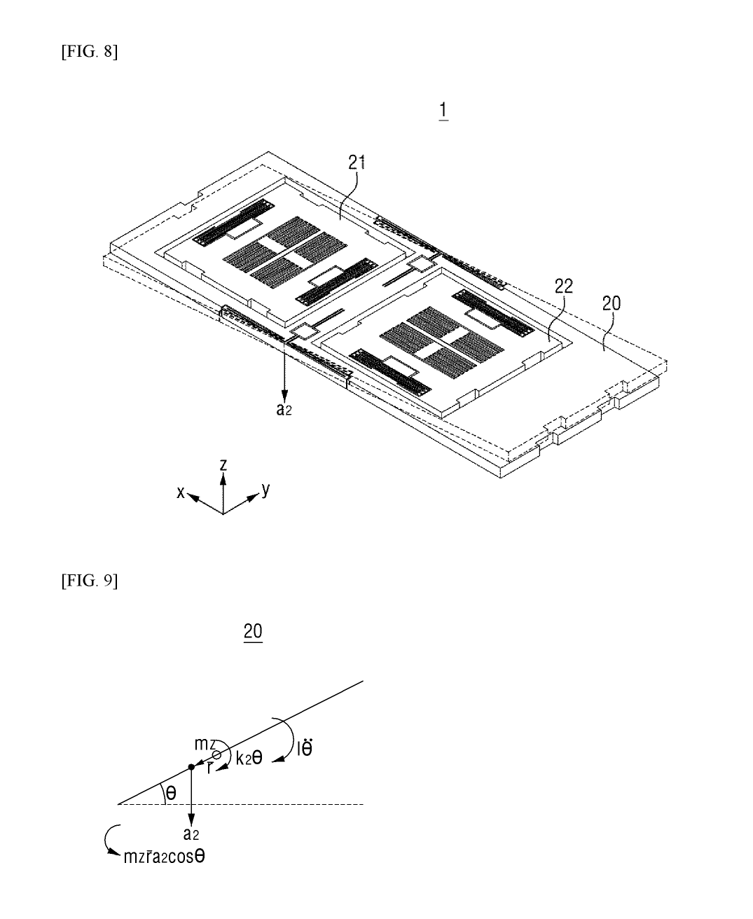

The operation and sensing principle of the three-axis integrated acceleration sensor according to an exemplary embodiment of the present invention upon the application of a z-axis direction acceleration from the outside will hereinafter be described with reference to FIGS. 8 and 9.

FIG. 8 is a perspective view illustrating a case where the z-axis sensor mass 20 of the three-axis integrated acceleration sensor according to an exemplary embodiment of the present invention vibrates.

Referring to FIG. 8, due to acceleration applied to the three-axis integrated acceleration sensor according to an exemplary embodiment of the present invention in the z-axis direction, the center of gravity of the z-axis sensor mass 20 does not coincide with the rotation support axis, and the z-axis sensor mass 20 rotates about the rotation support axis. In this case, the first springs 40 provide an elastic force against torsional movement, and as a result, the z-axis sensor mass 20 seesaws. When the z-axis sensor mass 20 rotates, movement generated at both ends of the z-axis sensor mass 20 in the x- or y-axis direction can be minimized by the dummy spring 43. Since both ends of the z-axis sensor mass 20 are displaced in the z-axis direction with respect to the first sensing electrode 50, a variation in static capacitance is generated with respect to the first sensing electrode 50. The third sensing electrode 52 measures the static capacitance variation and converts it into a z-axis acceleration value.

FIG. 9 is a free-body diagram of the z-axis sensor mass 20 of the three-axis integrated acceleration sensor according to an exemplary embodiment of the present invention.

Referring to FIG. 9, assuming that the z axis lies vertically, and that the z-axis sensor mass 20 moves by θ upon the application of acceleration from the outside in a downward direction, the equation of motion for the z-axis acceleration sensor is as indicated by Equation 2.

m_{z}ra₂ cos θ=k₂θ+I\ddot{θ}

Here, m_{z} denotes the mass of the z-axis sensor mass 20, k₂ denotes the rigidity of the first springs 40, a₂ denotes acceleration exerted externally on the three-axis integrated acceleration sensor according to an exemplary embodiment of the present invention in the z-axis direction, and r denotes the center of gravity of the z-axis sensor mass 20 with respect to the rotation shaft axis.

Referring to Equation 2, all the values except for a_{z} and θ can be known in the process of designing, θ can be measured from a variation in the static capacitance of the first sensing electrode 50, and thus, only a_{z} is left unknown. Accordingly, the acceleration applied externally in the z-axis direction can be calculated.

It will be understood by those skilled in the art that various changes in form and details may be made therein without departing from the spirit and scope of the present invention. Therefore, the scope of the present invention is defined not by the detailed description of the present invention but by the appended claims, and all differences within the scope will be construed as being included in the present invention. This invention is to be understood that the invention is not limited to the disclosed embodiments, but, on the contrary, is intended to cover various modifications and equivalent arrangements included within the spirit and scope of the appended claims.

Having described the exemplary embodiments of the present invention, it is further noted that it is readily apparent to those of reasonable skill in the art that various modifications may be made without departing from the spirit and scope of the present invention which is defined by the metes and bounds of the appended claims.

What is claimed is:

1. A three-axis integrated acceleration sensor comprising:
an x-axis sensor mass for sensing external acceleration input in a direction of a first axis that is parallel to a bottom wafer substrate;
a y-axis sensor mass for sensing external acceleration input in a direction of a second axis that is parallel to the bottom wafer substrate and is orthogonal to the first axis; and
a z-axis sensor mass formed to surround the x-axis sensor mass and the y-axis sensor mass, wherein the z-axis sensor mass is for sensing external acceleration input in a direction of a third axis that is orthogonal to the bottom wafer substrate.

2. The three-axis integrated acceleration sensor of claim 1, wherein when external acceleration is sensed using the x-axis sensor mass, the y-axis sensor mass, or the z-axis sensor mass, the x-axis sensor mass, the y-axis sensor mass, and the z-axis sensor mass do not affect one another.

3. The three-axis integrated acceleration sensor of claim 1, wherein the x-axis sensor mass, the y-axis sensor mass, and the z-axis sensor mass are disposed in parallel to the bottom wafer substrate.

4. The three-axis integrated acceleration sensor of claim 1, wherein
the x-axis sensor mass vibrates along the first-axis direction when external acceleration is input in the first-axis direction,
the y-axis sensor mass vibrates along the second-axis direction when external acceleration is input in the second-axis direction, and
the z-axis sensor mass rotates about a rotation support axis, which is parallel to the second axis, when external acceleration is input in the third-axis direction.

5. The three-axis integrated acceleration sensor of claim 4, further comprising:
first springs supporting movement in a direction of the rotation of the z-axis sensor mass;
second springs supporting movement in a direction of the vibration of the x-axis sensor mass; and
third springs supporting movement in a direction of the vibration of the y-axis sensor mass.

6. The three-axis integrated acceleration sensor of claim 5, wherein
the first springs include at least two springs disposed on both ends of the rotation support axis to support the z-axis sensor mass,
the second springs include at least two springs disposed at the front and the rear of the direction of the vibration of the x-axis sensor mass to support the x-axis sensor mass, and
the third springs include at least two springs disposed at the front and the rear of the direction of the vibration of the y-axis sensor mass to support the y-axis sensor mass.

7. The three-axis integrated acceleration sensor of claim 5, wherein
the first springs are connected to a dummy spring that is connected to the z-axis sensor mass, and
the dummy spring is formed to block movement of the z-axis sensor mass in the first-axis direction or in the second-axis direction.

8. The three-axis integrated acceleration sensor of claim 1, further comprising:
a first sensing electrode sensing displacement of the z-axis sensor mass;
a second sensing electrode sensing displacement of the x-axis sensor mass; and
a third sensing electrode sensing displacement of the y-axis sensor mass.

9. The three-axis integrated acceleration sensor of claim 8, wherein the second and third sensing electrodes have a parallel plate beam structure or a comb structure.

10. The three-axis integrated acceleration sensor of claim 1, further comprising:
first shielding walls disposed with a gap from outer surfaces of the z-axis sensor mass;
second shielding walls disposed with a gap from the x-axis sensor mass and the z-axis sensor mass; and
third shielding walls disposed with a gap from the y-axis sensor mass and the z-axis sensor mass.

11. The three-axis integrated acceleration sensor of claim 10, wherein the first shielding walls, the second shielding walls, and the third shielding walls are grounded.

12. The three-axis integrated acceleration sensor of claim 4, wherein the z-axis sensor mass is heavier on one side than the other side thereof with respect to the rotation support axis.

13. The three-axis integrated acceleration sensor of claim 5, wherein the first springs, the second springs, and the third springs are supported by anchors that have no movement.

14. The three-axis integrated acceleration sensor of claim 4, wherein the rotation support axis of the z-axis sensor mass traverses between the x-axis sensor mass and the y-axis sensor mass.
